(19) United States
(12) Patent Application Publication
(10) Pub. No.: US 2016/0349318 A1
(43) Pub. Date: Dec. 1, 2016

(54) Dynamic Clock Chain Bypass

(71) Applicant: Avago Technologies General IP (Singapore) Pte. Ltd, Singapore (SG)

(72) Inventors: Daryl Pereira, Bangalore Karnataka (IN); Sekar Manickam, Bangalore Karnataka (IN); Aanand Venkatachalam, Bangalore Karnataka (IN)

(21) Appl. No.: 14/721,142

(22) Filed: May 26, 2015

(51) Int. Cl. G01R 31/3177; G01R 31/317

(52) U.S. Cl. CPC G01R 31/3177; G01R 31/31727

(57) ABSTRACT

An apparatus for testing an electronic circuit includes a clock scan chain input, a clock scan chain output, and a number of clock controllers connected in series in a clock scan chain between the clock scan chain input and the clock scan chain output. Each of the clock controllers includes an input, a bypass flip flop connected to the input, a number of clock control bit flip flops connected in series to an output of the bypass flip flop, a bypass multiplexer having a first input connected to an output of a last of the clock control bit flip flops and a second input connected to the output of the bypass flip flop, and a holding flip flop having an input connected to the output of the bypass flip flop and an output connected to a select input of the bypass multiplexer.

### FIELD OF THE INVENTION

Various embodiments of the present invention provide systems and methods for dynamic clock chain optimization for at-speed tests in integrated circuits.

### BACKGROUND

Testing of complex integrated circuits is a complex task, made more difficult by the limited number of input and output pins (I/O's) available for large circuits. In one technique for testing, flip flops in the circuit are serially connected to form a shift register, and test patterns are shifted into the circuit to configure the flip flops in a test mode. The contents of the flip flops can be used to configure the circuit as it is tested, with the results being placed in the flip flops to be shifted out. The results read from the flip flops can then be compared with expected values based on the input test pattern to determine whether the circuit functioned properly. Tests can be run with a slow clock or shift clock supplied through an I/O pin, also used to shift in the test patterns. However, some circuit failures exhibit only when running at full speed. To detect such failures, a transition fault model or “at-speed” test is used. An on-chip clocking (OCC) controller selects the slower external shift clock when shifting in test patterns, and transitions to a full speed internal phase-locked loop (PLL) clock when performing the test. Furthermore, in order to target complex faults such as those in memory circuits, designs can use multiple capture cycles when performing the test. Dynamic control bits or clock control bits inside the on-chip clocking controller are driven as a scan chain by test patterns from automatic test pattern generator (ATPG) tools to control the number of clock pulses for a given test pattern in at-speed tests. Each bit, when enabled, leads to a capture clock pulse before shifting out the test results. However, unlike scan chains, clock scan chains cannot be easily driven by compression logic, resulting in very long chains that dictate the total test time.

### BRIEF SUMMARY

Some embodiments of the present invention provide an apparatus for testing an electronic circuit including a clock scan chain input, a clock scan chain output, and a number of clock controllers connected in series in a clock scan chain between the clock scan chain input and the clock scan chain output. Each of the clock controllers includes an input, a bypass flip flop connected to the input, a number of clock control bit flip flops connected in series to an output of the bypass flip flop, a bypass multiplexer having a first input connected to the output of a last of the clock control bit flip flops and a second input connected to an output of the bypass flip flop, and a holding flip flop having an input connected to the output of the bypass flip flop and an output connected to a select input of the bypass multiplexer.

This summary provides only a general outline of some embodiments of the invention. The phrases “in one embodiment,” “according to one embodiment,” “in various embodiments”, “in one or more embodiments”, “in particular embodiments” and the like generally mean the particular feature, structure, or characteristic following the phrase is included in at least one embodiment of the present invention, and may be included in more than one embodiment of the present invention. Importantly, such phrases do not necessarily refer to the same embodiment. This summary provides only a general outline of some embodiments of the invention. Additional embodiments are disclosed in the following detailed description, the appended claims and the accompanying drawings.

### BRIEF DESCRIPTION OF THE DRAWINGS

A further understanding of the various embodiments of the present invention may be realized by reference to the figures which are described in remaining portions of the specification. In the figures, like reference numerals may be used throughout several drawings to refer to similar components.

FIG. 1 depicts a scan chain testing system and an integrated circuit under test having dynamic clock chain optimization in accordance with some embodiments of the present invention;

FIG. 2 depicts scan chain logic including a decompressor and a compressor with an uncompressed clock control block for use with dynamic clock chain optimization in accordance with some embodiments of the present invention;

FIG. 3 depicts an on-chip clocking subsystem with an example of two on-chip clock controllers with dynamic clock chain optimization in accordance with some embodiments of the present invention; and

FIG. 4 depicts a flow diagram showing a method for dynamic clock chain optimization and bypass in an on-chip clocking subsystem in accordance with some embodiments of the present invention.

### DETAILED DESCRIPTION OF THE INVENTION

Various embodiments of the present invention provide systems and methods for dynamic clock chain length while testing an integrated circuit to optimize or reduce the amount of time required to perform the test. Embodiments of the invention will be illustrated herein in conjunction with exemplary testing systems and corresponding integrated circuits comprising scan test circuitry with dynamic clock chain length for supporting at-speed scan testing of those integrated circuits. It should be understood, however, that embodiments of the invention are more generally applicable to any testing system or associated integrated circuit in which it is desirable to provide reduced test time and/or lower power consumption during scan testing by selectively bypassing portions of a scan chain.

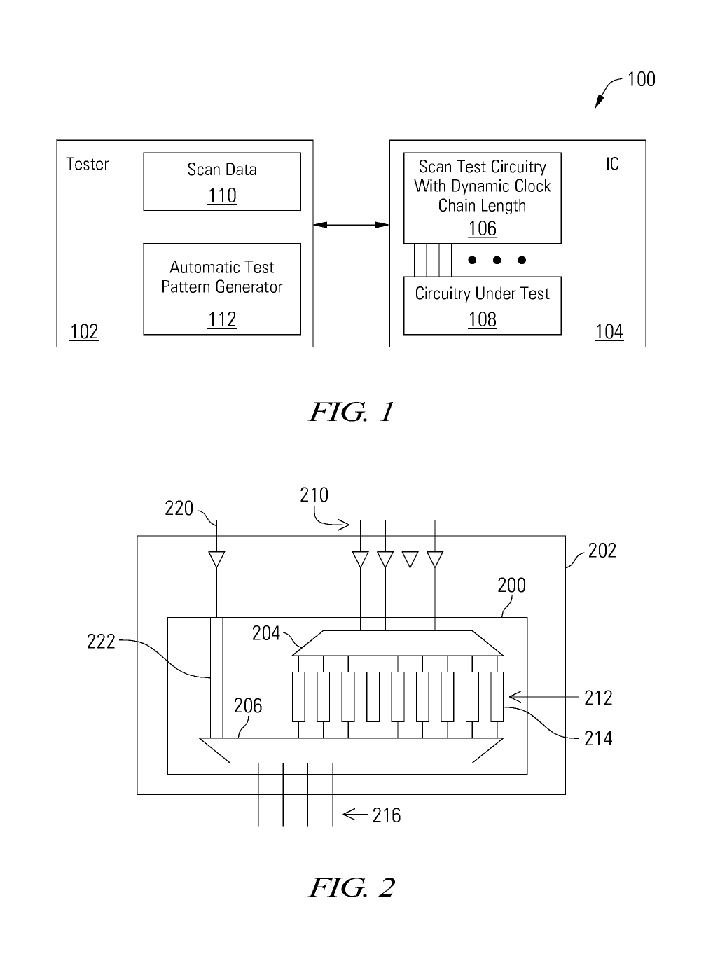

FIG. 1 depicts an embodiment of the invention in which a testing system 100 comprises a tester 102 and an integrated circuit under test 104. The integrated circuit 104 comprises scan test circuitry with dynamic clock chain length 106 that is coupled to internal circuitry 108 that is subject to testing utilizing the scan test circuitry 106. The scan test circuitry 106 comprises dedicated test logic inserted in the integrated circuit 104 to facilitate manufacturing testing and other testing in a Design-For-Testability technique.

The tester 102 stores scan data 110 associated with scan testing of the integrated circuit 104. Such scan data may correspond to test patterns provided by an automatic test pattern generator (ATPG) 112 and result vectors from the integrated circuit 104 generated by the tests. In other embodiments, at least a portion of the tester 102, such as the automatic test pattern generator 112, may be incorporated into the integrated circuit 104. Alternatively, the entire tester 102 may be incorporated into the integrated circuit 104. Test patterns from the tester 102 are shifted into the scan test circuitry 106 in the integrated circuit 104 during shift cycles and are used to configure scan chains of flip flops. The scan chains are configured to provide input to combinational logic in the circuitry under test 108 and, after the combinational logic has processed the input, to capture functional data from the combinational logic during capture cycles. The functional data is shifted out of the scan chains in the scan test circuitry 106 and provided to the tester 102 where it can be stored, compared to expected values, and/or otherwise analyzed to identify any faults in the circuitry under test 108 in the integrated circuit 104. The test patterns can be generated by the automatic test pattern generator 112 in any suitable manner, such as, but not limited to, combinational and sequential generation. Based upon the disclosure provided herein, one of ordinary skill in the art will recognize a variety of automatic test pattern generators that can be used in relation to different embodiments of the present invention.

The particular configuration of testing system 100 as shown in FIG. 1 is exemplary only, and the testing system 100 in other embodiments may include other elements in addition to or in place of those specifically shown, including one or more elements of a type commonly found in a conventional implementation of such a system. For example, various elements of the tester 102 or other parts of the system 100 may be implemented, by way of illustration only and without limitation, utilizing a microprocessor, central processing unit (CPU), digital signal processor (DSP), application-specific integrated circuit (ASIC), field-programmable gate array (FPGA), or other type of data processing device, as well as portions or combinations of these and other devices.

In some embodiments, the scan test circuitry with dynamic clock chain length 106 includes on-chip clock controllers (OCC) for switching between a slower scan clock, used to shift data in and out of the integrated circuit 104 from the tester 102 and, a faster internal clock in the integrated circuit 104 used for at-speed tests. In some embodiments, the faster internal clock is derived from a phase-locked loop (PLL) in the integrated circuit 104. The on-chip clock controllers include clock control bits comprising chains of flip flops, driven as a clock scan chain by test patterns from the automatic test pattern generator 112 to control the number of clock pulses for a given test pattern in at-speed tests. Each bit, when enabled, leads to a capture clock pulse before shifting out the test results.

Embodiments of the invention may be configured to utilize compressed or uncompressed scan testing. However, the illustrative embodiment shown in FIG. 2 will be described primarily in the context of compressed scan testing. While the scan chains of Design-For-Testability and Automatic Test Pattern Generation can generally provide excellent test coverage of each gate and path in a circuit design, large integrated circuits have a high ratio of combinational logic to be tested per available I/O pin on the integrated circuit. As a result, uncompressed test patterns for a large integrated circuit require an undesirably long period of time to scan in and yield an undesirably large volume of output test data. Furthermore, when an automatic test pattern generator 112 generates a test pattern for a fault or set of faults, only a small percentage of the flip flops in the scan chain need to have specific values, with the rest of the flip flops in the scan chain having a “don't care” condition. In other words, the values in these remaining flip flops in the scan chain do not affect the test results for this hypothetical test pattern, and these remaining flip flops in the scan chain can be filled with random data or with any desired values. In order to reduce the time required to scan in the test pattern and to scan out the test results, the test pattern can be compressed based on the fact that only a small subset of values in the test pattern need to have specific values and the rest are “don't care”.

Turning to FIG. 2, scan test circuitry 200 in an integrated circuit 202 is depicted, including a decompressor 204 and a compressor 206. Compressed test patterns received at scan inputs 210 are decompressed in the decompressor 204, and the resulting decompressed test patterns are shifted into scan chains 212 (e.g., scan chain 214). The decompression algorithm inserts the values in critical locations in the test patterns as specified by the automatic test pattern generator 112 in order to test for particular faults, and fills non-critical locations in the test patterns with random values or using any other suitable algorithm to complete the test patterns.

The combinational logic in the integrated circuit 202 then processes the values in the scan chains 212, and the resulting functional data from the combinational logic is captured in the scan chains 212. The compressor 206 or test response compactor compresses the functional data, outputting the pertinent test results from scan outputs 216. Based upon the disclosure provided herein, one of ordinary skill in the art will recognize a variety of decompression and compression algorithms and circuits that can be used in relation to different embodiments of the present invention. In some embodiments, the decompressor 204 and the compressor 206 apply continuous flow algorithms, enabling test patterns and functional data to be shifted in and out of the scan test circuitry in a continuous manner during tests.

Again, at-speed tests can be used to test combinational logic at full speed, the normal operating speed of the integrated circuit, rather than at the slower speed of the scan clock used when shifting test patterns and functional data in and out of scan chains, in order to detect faults that occur only at high speed. A deficient net or connection in an integrated circuit might manage to transmit the correct value when sampled at wider intervals with a slower clock, although it fails at full speed due, for example, to a limited slew rate caused by a physical flaw in the circuit.

Furthermore, detection of some complex faults, such as the ones in memories, can require multiple capture cycles to target the faults. The clock control bits in the on-chip clock controller, driven as a clock scan chain 222 by test patterns from the automatic test pattern generator through scan in pin(s) 220, control the number of clock pulses for a given test pattern in the at-speed tests. The clock control bit flip flops in the on-chip clock controllers of the scan test circuitry are stitched into a separate clock scan chain 222 outside the circuitry under test. Each bit, when enabled, leads to a capture clock pulse before shifting out the test results. If a clock domain in the integrated circuit is not pulsed during a particular test, the automatic test pattern generator 112 generates a test pattern which sets each of the clock control bit flip flops to 0 at the end of the shift cycles for that test pattern. When the test is then executed, none of the clock control bits generates a clock pulse, and no combinational logic circuits controlled by the clock from the on-chip clock controller are triggered during the test. If the clock domain in the integrated circuit is involved in a particular test, the number and timing of clock pulses can be controlled by which of the clock control bit flip flops are set to 1 at the end of the shift cycles for that test pattern.

Notably, the clock scan chain 222 in some embodiments is placed outside of the compression logic and does not pass through the decompressor 204, allowing the value of every flip flop in the clock scan chain 222 to be controlled. None of the clock control bits are “don't care”, they cannot be randomly filled because every clock control bit has an impact on how many clock pulses are fired during a test.

However, with every bit in the test patterns for the clock scan chain 222 being controllable, the test patterns received at scan input 220 for the clock scan chain 222 can be much longer than corresponding compressed test patterns received at scan inputs 210, so that shifting in the test patterns for the clock scan chain 222 is much slower and dominates the test time. Rather than use additional scan inputs to divide clock scan chains, which may not be possible with large circuits having limited number of I/O pins, the dynamic clock chain length optimization disclosed herein enables clock control bit flip flops to be bypassed for clock domains which are not pulsed for a given test pattern. Generally, the automatic test pattern generator 112 will not pulse all clock domains in the integrated circuit with a test pattern during a particular test. The automatic test pattern generator 112 dynamically determines which clock domains to test together based on interacting logic and synchronous paths for a given pattern. This determination of clock domains involved in a particular test can be performed in a similar manner to determining which bits of a test pattern are “don't care” for other scan chains, based on the circuit design.

In some embodiments, the scan out of the clock scan chain 222 is compressed in compressor 206. The scan output from the clock scan chain 222 need not be observed in all patterns since it doesn't capture any functional faults, and a single shift pattern would gain full coverage on clock chain faults.

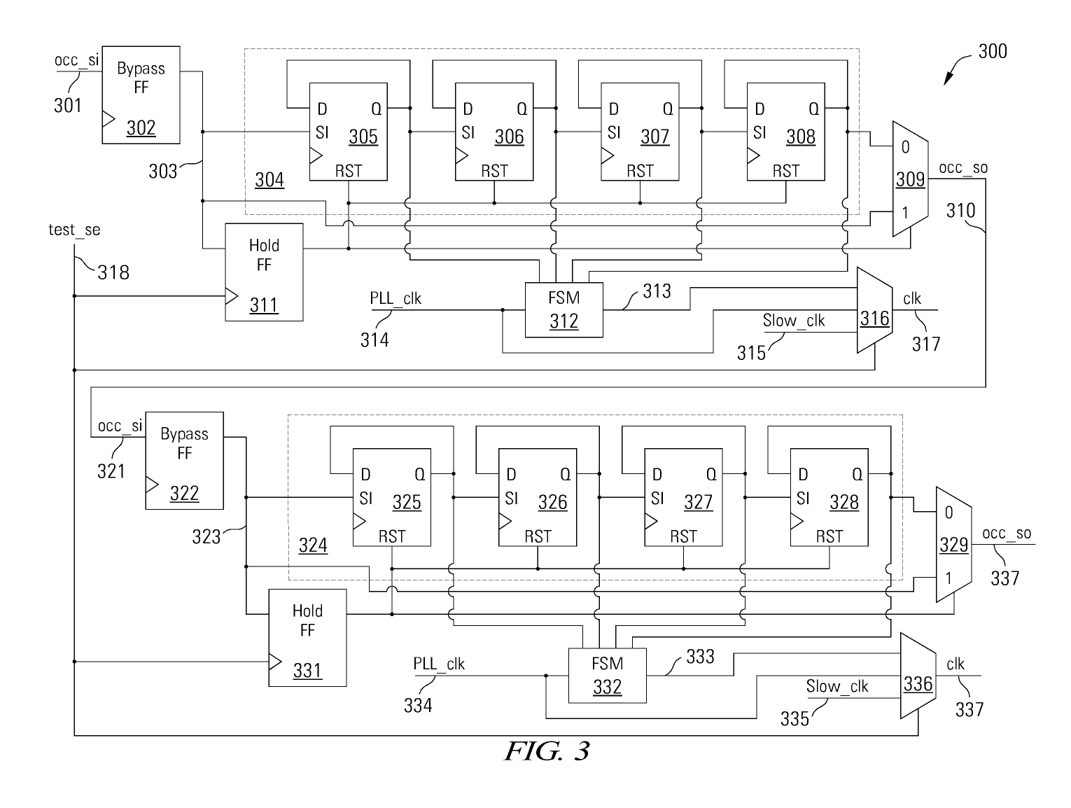

Turning now to FIG. 3, an on-chip clocking subsystem 300 is depicted with an example of two on-chip clock controllers with dynamic clock chain optimization connected in a clock scan chain in accordance with some embodiments of the present invention.

In a first of the example on-chip clock controllers, an on-chip clock scan input 301 receives test patterns for the clock scan chain. A bypass flip flop 302 latches each bit of the test pattern as it is shifted in. A clock control block 304 is connected to the output 303 of the bypass flip flop 302, and contains an example chain of four clock control bit flip flops 305, 306, 307, 308. The first clock control bit flip flop 305 has a scan in (SI) input connected to the output 303 of the bypass flip flop 302. The scan in input of the second clock control bit flip flop 306 is connected to the Q output of the first clock control bit flip flop 305. The scan in input of the third clock control bit flip flop 307 is connected to the Q output of the second clock control bit flip flop 306. The scan in input of the fourth clock control bit flip flop 308 is connected to the Q output of the third clock control bit flip flop 307. The D input of each of the clock control bit flip flops 305, 306, 307, 308 is connected to its own Q output.

A holding flip flop 311 in the first of the example on-chip clock controllers has an input connected to the output of the bypass flip flop 302. A bypass multiplexer 309 has a first input connected to the output of the clock control block 304, in this case, the Q output of the fourth clock control bit flip flop 308. The bypass multiplexer 309 has a second input connected to the output 303 of the bypass flip flop 302. The select input of the bypass multiplexer 309 is connected to the output of the holding flip flop 311. The output of the bypass multiplexer 309 provides the scan output 310 for the first example on-chip clock controller.

In some embodiments, the reset lines on the clock control bit flip flops 305, 306, 307, 308 are also connected to the output of the holding flip flop 311.

A clock multiplexer 316 selects the clock 317 for use during testing, selecting from a slow clock 315 or scan clock used when shifting in test patterns and shifting out functional data, an internal full speed clock 314 from a phase-locked loop, and a selective pulse clock 313 or at-speed clock for use in at-speed tests, generated by a finite state machine 312. The finite state machine 312 generates the selective pulse clock 313 based on a combination of the internal full speed clock 314 and the outputs of the clock control bit flip flops 305, 306, 307, 308 in the clock control block 304. For a given test pattern, the finite state machine 312 passes pulses from the internal full speed clock 314 only when the clock control bit flip flop 305, 306, 307, 308 corresponding to each pulse is configured to supply the pulse, e.g., contains a ‘1’.

In some embodiments, the bypass flip flop 302 and the clock control bit flip flops 305, 306, 307, 308 in the clock control block 304 are clocked by the slow clock 315, which is provided by the tester (e.g., 102) through an I/O pin on the integrated circuit.

In a second of the example on-chip clock controllers, an on-chip clock scan input 321 receives test patterns via the scan output 310 from the first of the example on-chip clock controllers. A bypass flip flop 322 latches each bit of the test pattern as it is shifted in. A clock control block 324 is connected to the output 323 of the bypass flip flop 322, and contains an example chain of four clock control bit flip flops 325, 326, 327, 328. The first clock control bit flip flop 325 has a scan in (SI) input connected to the output 323 of the bypass flip flop 322. The scan in input of the second clock control bit flip flop 326 is connected to the Q output of the first clock control bit flip flop 325. The scan in input of the third clock control bit flip flop 327 is connected to the Q output of the second clock control bit flip flop 326. The scan in input of the fourth clock control bit flip flop 328 is connected to the Q output of the third clock control bit flip flop 327. The D input of each of the clock control bit flip flops 325, 326, 327, 328 is connected to its own Q output.

A holding flip flop 331 in the second of the example on-chip clock controllers has an input connected to the output of the bypass flip flop 322. A bypass multiplexer 329 has a first input connected to the output of the clock control block 324, in this case, the Q output of the fourth clock control bit flip flop 328. The bypass multiplexer 329 has a second input connected to the output 323 of the bypass flip flop 322. The select input of the bypass multiplexer 329 is connected to the output of the holding flip flop 331. The output of the bypass multiplexer 329 provides the scan output 337 for the second example on-chip clock controller.

In some embodiments, the reset lines on the clock control bit flip flops 325, 326, 327, 328 are also connected to the output of the holding flip flop 331.

A clock multiplexer 336 selects the clock 337 for use during testing, selecting from a slow clock 335 or scan clock used when shifting in test patterns and shifting out functional data, an internal full speed clock 334 from a phase-locked loop, and a selective pulse clock 333 for use in at-speed tests, generated by a finite state machine 332. The finite state machine 332 generates the selective pulse clock 333 based on a combination of the internal full speed clock 334 and the outputs of the clock control bit flip flops 325, 326, 327, 328 in the clock control block 324. For a given test pattern, the finite state machine 332 passes pulses from the internal full speed clock 334 only when the clock control bit flip flop 325, 326, 327, 328 corresponding to each pulse is configured to supply the pulse, e.g., contains a ‘1’.

In some embodiments, the bypass flip flop 322 and the clock control bit flip flops 325, 326, 327, 328 in the clock control block 324 are clocked by the slow clock 335, which is provided by the tester (e.g., 102) through an I/O pin on the integrated circuit.

A test scan enable signal 318 is used to select the clocks in clock multiplexers 316, 336, and to latch the outputs 303, 323 of the bypass flip flops 302, 322 in the holding flip flops 311, 331.

The number of on-chip clock controllers in a clock scan chain and the number of clock control bits in each on-chip clock controller is not limited to the two on-chip clock controllers and the four clock control bits per on-chip clock controller illustrated in FIG. 3. For example, the number of clock control bits per on-chip clock controller can be determined based on the sequential depth involving non-scan cells, memories in the design, inter-domain testing, etc. In some embodiments, for example, each on-chip clock controller contains 10-12 clock control bits.

In one example of the embodiment of FIG. 3, the first on-chip clock controller is in a first clock domain and the second on-chip clock controller is in a second clock domain. During operation, if for a particular test pattern the clock domain of the first on-chip clock controller will not be pulsed and the clock domain of the second on-chip clock controller will be pulsed, a ‘1’ is stored in the bypass flip flop 302 of the first on-chip clock controller and a ‘0’ is stored in the bypass flip flop 322 of the second on-chip clock controller at the end of the preceding test pattern. When the test scan enable signal 318 is asserted, the ‘1’ from bypass flip flop 302 is latched into the holding flip flop 311, and the ‘0’ from bypass flip flop 322 is latched into the holding flip flop 331. The ‘1’ in holding flip flop 311 configures the bypass multiplexer 309 to select the output 303 of the bypass flip flop 302, bypassing the clock control bit flip flops 305, 306, 307, 308 so that the test pattern being shifted into the clock scan chain need not contain entries corresponding to the bypassed clock control bit flip flops 305, 306, 307, 308. The ‘1’ in holding flip flop 311 also holds the clock control bit flip flops 305, 306, 307, 308 in the first on-chip clock controller in the reset state, reducing power consumption and switching during the test. The ‘0’ in holding flip flop 331 configures the bypass multiplexer 329 to select the output of the clock control block 324 so that the test pattern is shifted into and configures the clock control bit flip flops 325, 326, 327, 328 of the second on-chip clock controller. The ‘0’ in holding flip flop 331 also releases the clock control bit flip flops 325, 326, 327, 328 in the second on-chip clock controller from the reset state. Thus, the test pattern need contain entries only for the clock control bit flip flops of the second on-chip clock controller, shortening the test pattern by dynamically bypassing the clock control bit flip flops of the first on-chip clock controller and reducing the number of clock cycles needed to scan in the test pattern. An extra bypass configuration bit is added to the test pattern for each bypass flip flop, based on whether the clock domain corresponding to each bypass flip flop will be pulsed during the test for the next test pattern. The holding flip flops latch the data from the bypass flip flops on every assertion (or rising edge) of the test scan enable signal.

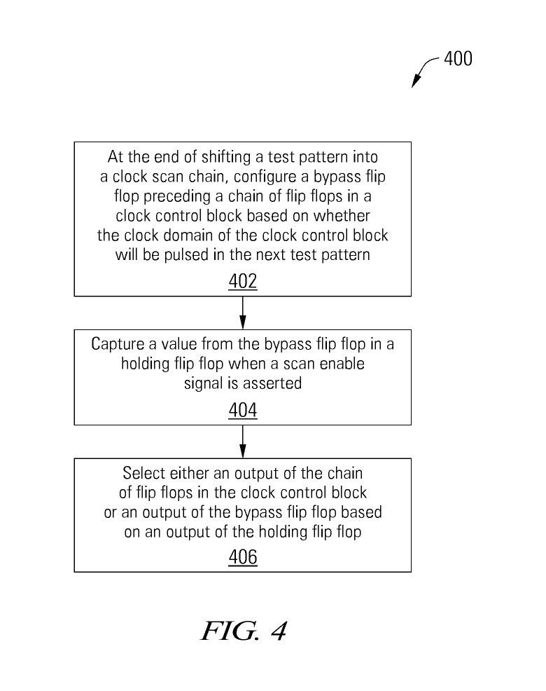

Turning now to FIG. 4, flow diagram 400 depicts a method for dynamic clock chain optimization and bypass in an on-chip clocking subsystem in accordance with some embodiments of the present invention. At the end of shifting a test pattern into a clock scan chain, a bypass flip flop upstream of a chain of flip flops in a clock control block is configured based on whether the clock domain of the clock control block will be pulsed in the next test pattern. (Block 402) In some embodiments, if the clock domain will be pulsed in the next test pattern, a ‘0’ is shifted into the bypass flip flop at the end of the current test pattern. If the clock domain will not be pulsed in the next test pattern, a ‘1’ is shifted into the bypass flip flop. The value from the bypass flip flop is captured in a holding flip flop when a scan enable signal is asserted. (Block 404) A selection is made between the output of the chain of clock control bit flip flops in the clock control block and an output of the bypass flip flop based on an output of the holding flip flop. (Block 406) In some embodiments, this selection is made by a bypass multiplexer having a first input connected to the output of the chain of flip flops in the clock control block, a second input connected to the output of the bypass flip flop, and a selection input connected to the output of the holding flip flop. For the embodiments in which a ‘0’ is stored in the bypass flip flop when the clock domain is pulsed in the next test pattern, the bypass multiplexer selects the output of the bypass flip flop when the holding flip flop contains a ‘1’, and selects the output of the chain of flip flops in the clock control block when the holding flip flop contains a ‘0’.

In some embodiments, the output of the holding flip flop is also used to control a reset state of the flip flops in the clock control block. When the clock domain will not be pulsed during a test pattern, and the holding flip flop is set to ‘1’, the flip flops in the clock control block are all held in a reset state when they are bypassed. This can save power and reduce switching in the circuit.

It should be noted that the various blocks discussed in the above description may be implemented in integrated circuits along with other functionality. Such integrated circuits may include all of the functions of a given block, system or circuit, or only a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that some functions of the blocks, systems or circuits discussed herein may be implemented in either software or firmware in combination with hardware circuits.

In conclusion, the present invention provides novel apparatuses and methods for integrated circuit testing systems with dynamic clock chain length. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. An apparatus for testing an electronic circuit, comprising:
a clock scan chain input;
a clock scan chain output;
a clock controller connected in a clock scan chain between the clock scan chain input and the clock scan chain output,
wherein the clock controller comprises:
an input;
a bypass flip flop connected to the input;
a plurality of clock control bit flip flops connected in series to an output of the bypass flip flop;
a bypass multiplexer having a first input connected to an output of a last of the clock control bit flip flops and a second input connected to the output of the bypass flip flop; and
a holding flip flop having an input connected to the output of the bypass flip flop and an output connected to a select input of the bypass multiplexer.

2. The apparatus of claim 1, further comprising a test scan enable signal, wherein the holding flip flop is clocked by the test scan enable signal.

3. The apparatus of claim 1, wherein each of the clock control bit flip flops comprises a reset input connected to the output of the holding flip flop.

4. The apparatus of claim 1, wherein the clock controller further comprises a state machine having a phase-locked loop clock input, a plurality of pulse control inputs connected to outputs of the plurality of clock control bit flip flops, and an at-speed test clock output.

5. The apparatus of claim 4, wherein the clock controller further comprises a clock multiplexer having a first input connected to the at-speed test clock output, a second input connected to a scan clock, and a select input connected to a test scan enable signal.

6. The apparatus of claim 5, wherein the clock multiplexer further comprises a third input connected to the phase-locked loop clock input.

7. The apparatus of claim 1, wherein each of the plurality of clock control bit flip flops comprise a scan-in input and a Q output, wherein the scan-in input of a first one of the plurality of clock control bit flip flops is connected to the output of the bypass flip flop, and wherein the scan in-input of a remainder of the plurality of clock control bit flip flops is connected to the Q output in a preceding one of the plurality of clock control bit flip flops.

8. The apparatus of claim 7, wherein each of the plurality of clock control bit flip flops further comprises a D input connected to its Q output.

9. The apparatus of claim 1, further comprising a test pattern decompressor, a functional data compressor, and a plurality of scan chains connected between the test pattern decompressor and the functional data compressor, wherein the clock scan chain is connected to the functional data compressor but not to the test pattern decompressor.

10. A method of testing an electronic circuit, comprising:
at the end of shifting a test pattern into a clock scan chain in the electronic circuit, configuring a bypass flip flop upstream of a chain of flip flops in a clock control block based on whether a clock domain of the clock control block will be pulsed in a next test pattern;
latching a value from the bypass flip flop in a holding flip flop when a scan enable signal is asserted; and
selecting either an output of the chain of flip flops in the clock control block or an output of the bypass flip flop based on an output of the holding flip flop.

11. The method of claim 10, further comprising generating the test pattern in an automatic test pattern generator.

12. The method of claim 11, further comprising determining in the automatic test pattern generator whether the clock domain will be pulsed in the next test pattern.

13. The method of claim 10, further comprising shifting the test pattern through the clock scan chain while bypassing the chain of flip flops in the clock control block when the holding flip flop is configured in a bypass mode.

14. The method of claim 10, wherein the selecting is performed by a bypass multiplexer having a first input connected to the output of the chain of flip flops, a second input connected to the output of the bypass flip flop, and a select input connected to the output of the holding flip flop.

15. The method of claim 10, further comprising holding the chain of flip flops in a reset state when they are bypassed.

16. The method of claim 15, wherein holding the chain of flip flops in a reset state comprises controlling a reset input of each of the flip flops with the output of the holding flip flop.

17. The method of claim 10, wherein configuring the bypass flip flop comprises latching a ‘0’ in the bypass flip flop when the clock domain of the clock control block will be pulsed in the next test pattern.

18. The method of claim 10, wherein configuring the bypass flip flop comprises latching a ‘1’ in the bypass flip flop when the clock domain of the clock control block will not be pulsed in the next test pattern.

19. An integrated circuit testing system, comprising:
automatic test pattern generation means configured to dynamically determine whether each of a plurality of clock domains in an integrated circuit under test will be pulsed in a test and to generate a test pattern including bypass configuration bits for the next test; and
scan test means in the integrated circuit under test configured to bypass clock control bit flip flops in a clock scan chain based on the bypass configuration bits.

20. The integrated circuit testing system of claim 19, further comprising means for holding the clock control bit flip flops in a reset state when they are bypassed.
